(19) United States
(12) Patent Application Publication
(10) Pub. No.: US 2012/0256522 A1
(43) Pub. Date: Oct. 11, 2012

(54) MAGNETIC SENSOR DEVICE, METHOD OF MANUFACTURING THE SAME, AND MAGNETIC SENSOR APPARATUS

(75) Inventors: Shigeo ITO, Nagaokakyo-shi (JP); Yoshihiro Ito, Nagaokakyo-shi (JP); Michio Kadota, Nagaokakyo-shi (JP)

(73) Assignee: MURATA MANUFACTURING CO., LTD., Nagaokakyo-shi (JP)

(21) Appl. No.: 13/528,879

(22) Filed: Jun. 21, 2012

Related U.S. Application Data
(63) Continuation of application No. PCT/JP2010/071897, filed on Dec. 7, 2010.

(30) Foreign Application Priority Data
Dec. 24, 2009 (JP) 2009-292985

(51) Int. Cl. H01L 41/047; H01L 41/22

(52) U.S. Cl. 310/313 B; 29/25.35

(57) ABSTRACT

A magnetic sensor device includes a piezoelectric substrate and an IDT electrode disposed on the piezoelectric substrate. At least a portion of the IDT electrode is made of a ferromagnetic metal and the duty ratio of the IDT electrode is higher than about 0.5 and lower than or equal to about 0.99.

### BACKGROUND OF THE INVENTION

1. Field of the Invention

The present invention relates to magnetic sensor devices that are used in magnetic sensor apparatuses, such as magnetic open/close sensors. In particular, the present invention relates to magnetic sensor devices that utilize surface acoustic waves, methods of manufacturing the magnetic sensor devices, and magnetic sensor apparatuses including the magnetic sensor devices.

2. Description of the Related Art

To date, surface acoustic wave apparatuses have been widely used in resonators and band pass filters. Further, various sensors for measuring various materials and physical values utilizing a change in the resonance characteristics of acoustic wave apparatuses have been proposed.

For example, Japanese Unexamined Patent Application Publication No. 2007-517389 cited below discloses a method and apparatus for ultra-high-speed control of magnetic cells through the use of a surface acoustic wave device. In Japanese Unexamined Patent Application Publication No. 2007-517389, it is stated that an input side IDT electrode and an output side IDT electrode are formed on a piezoelectric substrate. A ferromagnetic material layer is stacked on a surface acoustic wave propagation path between the input side IDT electrode and the output side IDT electrode or on the input side IDT electrode. It is stated that a magnetic memory or a magnetic sensor can be formed by utilizing a change in a magnetic field in the ferromagnetic material layer which is caused by magnetoelastic coupling due to distortion that is generated by propagation of a surface acoustic wave.

On the other hand, a surface acoustic wave device sensor illustrated in FIG. 9 is disclosed in Japanese Unexamined Patent Application Publication No. 2006-47229. A surface acoustic wave device sensor 101 includes an input side IDT electrode 103 and an output side IDT electrode 104 formed on a piezoelectric substrate 102. Here, a functional thin film 106 is formed on the piezoelectric substrate 102. The functional thin film 106 changes the characteristics of a propagating surface acoustic wave in accordance with changes in various types of environmental information and physicochemical parameters. Hence, it is stated that the various environmental and physicochemical parameters can be detected as a result of a change in the surface acoustic wave propagation characteristics. A sensor apparatus is disclosed that uses Fe—Pd, which is a type of magnetic shape memory material, as an example of the functional thin film material described above and detects distortion by utilizing the magnetostrictive effect and a magnet.

Further, Japanese Patent No. 3353742 discloses an SH surface acoustic wave resonator in which an IDT electrode made of a metal, such as Ta, having a higher specific gravity than crystal is formed on a crystal substrate. Here, it is stated that frequency variation due to variation, generated during etching, in the width of electrode fingers or film thickness can be suppressed by making the duty ratio of the electrode fingers of the surface acoustic wave resonator be 0.55-0.85. It is stated in Japanese Patent No. 3353742 that such an SH surface acoustic wave resonator is used in the resonators or filters mentioned above.

Although Japanese Unexamined Patent Application Publication No. 2007-517389 implies that a structure in which a ferromagnetic material layer is provided on a piezoelectric substrate of the surface acoustic wave device is applicable to a magnetic sensor, a specific structure adopted for a magnetic sensor is not disclosed. In other words, Japanese Unexamined Patent Application Publication No. 2007-517389 discloses only a specific method and an apparatus suitable for ultra-high-speed accessing and switching in magnetic cells.

On the other hand, regarding the surface acoustic wave device sensor 101 disclosed in Japanese Unexamined Patent Application Publication No. 2006-47229, it is stated that, by selecting the functional thin film 106, various physicochemical parameters, such as temperature, humidity, a load, air pressure, gas components, and magnetism can be detected as a result of a change in surface acoustic wave propagation characteristics caused by changes in these physicochemical parameters. However, specific description is given only about a sensor that detects distortion through the magnetostrictive effect by forming a layer composed of a magnetic memory material, such as Fe—Pd, on a surface acoustic wave propagation line.

In addition, since the surface acoustic wave device sensor 101 disclosed in Japanese Unexamined Patent Application Publication No. 2006-47229 has a structure in which the functional thin film 106 is provided on a surface acoustic wave propagation path between the input side IDT electrode and the output side IDT electrode or other surface acoustic wave propagation portions, reduction in size is difficult.

On the other hand, Japanese Patent No. 3353742 discloses only an SH surface acoustic wave resonator that is used as an electronic component, such as a resonator or band pass filter, for communication apparatuses. In other words, Japanese Patent No. 3353742 does not mention a magnetic sensor.

### SUMMARY OF THE INVENTION

Preferred embodiments of the present invention provide a magnetic sensor device that utilizes a surface acoustic wave and detects a change in a magnetic field or the like with high accuracy and that can be reduced in size, a method of manufacturing the magnetic sensor device, and a magnetic sensor apparatus that includes the magnetic sensor device.

A magnetic sensor device according to a preferred embodiment of the present invention includes a piezoelectric substrate and an IDT electrode disposed on the piezoelectric substrate. At least a portion of the IDT electrode is preferably made of a ferromagnetic metal. The duty ratio of the IDT electrode preferably is higher than about 0.5 and lower than or equal to about 0.99, for example.

In a specific aspect of the magnetic sensor device according to a preferred embodiment of the present invention, a first reflector and a second reflector respectively arranged on two sides of the IDT electrode are further provided. The duty ratios of the first and second reflectors preferably are higher than about 0.5 and lower than or equal to about 0.99, for example. In this case, the detection sensitivity is further increased.

In another specific aspect of the magnetic sensor device according to a preferred embodiment of the present invention, the piezoelectric substrate preferably is a crystal substrate and a magnetic sensor device is provided in which a change in the characteristics resulting from a change in temperature is small.

In still another specific aspect of the magnetic sensor device according to a preferred embodiment of the present invention, when a film thickness of the IDT electrode is H and a wavelength of a surface acoustic wave excited by the IDT electrode is λ, a normalized film thickness (H/λ)×100(%) of the IDT electrode preferably is larger or equal to about 0.4%, for example. In this case a sufficient sensitivity is obtained.

A magnetic sensor apparatus according to another preferred embodiment of the present invention includes the magnetic sensor device according to one of the above-described preferred embodiments of the present invention and a frequency measurement apparatus that measures a change in frequency in the magnetic sensor device.

The magnetic sensor apparatus according to a preferred embodiment of the present invention is widely used in a magnetic sensor apparatus to detect the strength and direction of a magnetic field, and is preferably used as a magnetic open/close sensor.

A method of manufacturing a magnetic sensor device according to a further preferred embodiment of the present invention includes a step of forming an IDT electrode which has a duty ratio that is higher than about 0.5 and lower than or equal to about 0.99, for example, and at least a portion of which is made of a ferromagnetic metal on a piezoelectric substrate, and a heating step of performing a heating process after the forming of the IDT electrode.

In the magnetic sensor device according to a preferred embodiment of the present invention, since at least a portion of the IDT electrode is made of a ferromagnetic metal, a change in a magnetic field can be detected using a change in the surface acoustic wave propagation characteristics due to a change in the surrounding magnetic field. In particular, since the duty ratio of the IDT electrode is higher than about 0.5 and lower than or equal to about 0.99, for example, detection sensitivity can be effectively increased. Further, since at least a portion of the IDT electrode is a ferromagnetic metal, a ferromagnetic material layer need not be provided in a portion other than the IDT electrode. Hence, the magnetic sensor device can be reduced in size.

Since the magnetic sensor apparatus according to a preferred embodiment of the present invention includes the magnetic sensor device of another preferred embodiment of the present invention and the frequency measurement apparatus described above, a change in a magnetic field can be detected with high accuracy by measuring a change in the output frequency of the magnetic sensor device due to a change in the magnetic field or the like.

Since the method of manufacturing a magnetic sensor device according to a preferred embodiment of the present invention includes only forming, on a piezoelectric substrate, an IDT electrode which has a duty ratio that is higher than about 0.5 and lower than or equal to about 0.99, for example, and at least a portion of which is formed of a ferromagnetic metal and then performing a heating process, the magnetic sensor device according to a preferred embodiment of the present invention can be provided using a relatively simple method. In addition, the sensitivity of the magnetic sensor device can be further increased through the above-described heating process, and a reduction in variations in the characteristics of the magnetic sensor device and the stabilization of the characteristics are realized.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of a magnetic sensor device according to a preferred embodiment of the present invention.

FIG. 2 is a schematic configuration diagram of a magnetic sensor apparatus according to a preferred embodiment of the present invention.

FIG. 3 is a diagram illustrating magnetic flux density as magnetic field strength versus distance from a magnet surface for a plurality of magnets with different sizes.

FIG. 4 is a diagram illustrating the rate of change of frequency in a magnetic sensor device versus magnetic flux density for various duty ratios.

FIG. 5 is a diagram illustrating the rate of change of frequency versus duty ratio.

FIG. 6 is a diagram illustrating the rate of change of frequency versus magnetic flux density for a normalized IDT electrode film thickness (%) of approximately 0.68%, 1.03%, 1.37%, or 1.71%.

FIG. 7 is a diagram illustrating the rate of change of frequency versus normalized electrode film thickness (%).

FIG. 8 is a diagram illustrating the rate of change of frequency versus magnetic flux density for the case where no heating is performed and the case where heating at about 200° C. or about 300° C. is performed, after the formation of an IDT electrode.

FIG. 9 is a schematic configuration diagram of an existing surface acoustic wave device sensor.

### DETAILED DESCRIPTION OF THE PREFERRED EMBODIMENTS

Hereinafter, specific preferred embodiments of the present invention will be described with reference to the drawings.

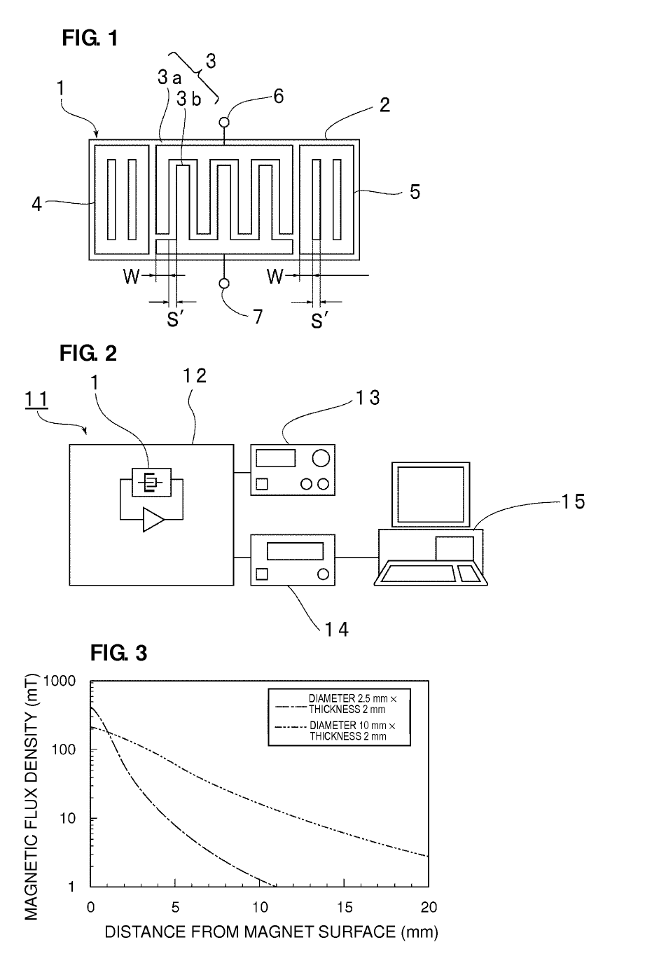

FIG. 1 is a plan view of a magnetic sensor device according to a preferred embodiment of the present invention.

A magnetic sensor device 1 of the present preferred embodiment includes a piezoelectric substrate 2. In the present preferred embodiment, the piezoelectric substrate 2 is preferably made of crystal, for example. However, the piezoelectric substrate 2 may be formed of a piezoelectric monocrystal, such as LiNbO₃ or LiTaO₃, or a piezoelectric ceramic, such as PZT. Preferably, the piezoelectric substrate 2 is made of crystal as in the present preferred embodiment. When the piezoelectric substrate 2 is a crystal substrate, variation in the characteristics due to a change in temperature can be reduced, compared with the cases in which other piezoelectric monocrystals are used.

Note that a 37° rotated Y-cut 90° X-propagation crystal substrate, for example, is preferably used as the piezoelectric substrate 2 in the present preferred embodiment. Hence, a surface acoustic wave that propagates when an IDT electrode 3 is excited is an SH surface acoustic wave.

The IDT electrode 3 is provided on the upper surface of the piezoelectric substrate 2. The IDT electrode 3 includes a first comb-shaped electrode 3a including a plurality of electrode fingers and a second comb-shaped electrode 3b including a plurality of electrode fingers. The electrode fingers of the first comb-shaped electrode 3a and the electrode fingers of the second comb-shaped electrode 3b are interdigitated.

The first comb-shaped electrode 3a of the IDT electrode 3 is connected to a first terminal 6 and the second comb-shaped electrode 3b is connected to a second terminal 7. A surface acoustic wave can be excited in the IDT electrode 3 by applying an AC electric field from the first and second terminals.

Reflectors 4 and 5 are respectively provided on the two sides of the IDT electrode 3 in the propagation direction of the surface acoustic wave. In the present preferred embodiment, the reflectors 4 and 5 preferably are each a grating reflector in which a plurality of electrode fingers are short-circuited at both ends.

As has been described above, in the present preferred embodiment, a one-port surface acoustic wave resonator is provided in which the reflectors 4 and 5 are respectively arranged on the two sides of the IDT electrode 3.

In the IDT electrode 3 and the reflectors 4 and 5, at least a portion thereof preferably is made of a ferromagnetic metal. In the present preferred embodiment, the IDT electrode 3 and the reflectors 4 and 5 are preferably made of Ni, which is a ferromagnetic metal. However, not limited to Ni, examples of appropriate ferromagnetic metals that can be used include Co, Fe, a Tb—Fe alloy, and alloys of these metals.

The whole IDT electrode 3 is preferably made of a ferromagnetic metal such as Ni. As a result, the sensitivity is increased. However, the IDT electrode 3 may be formed such that a portion thereof is made of a ferromagnetic metal while the rest is made of a metal other than a ferromagnetic metal.

Further, an adhesive layer may be arranged so that the IDT electrode 3 is tightly fixed to the piezoelectric substrate 2. An adhesive layer is disposed between the IDT electrode 3 and the piezoelectric substrate 2 as an underlying layer of the IDT electrode 3 so as to have the same planar shape as the IDT electrode 3. Hence, the adhesive layer is not illustrated in FIG. 1. In the present preferred embodiment, a Ti layer with a thickness of about 5 nm is preferably provided as an adhesive layer, for example. Note that the material forming the adhesive layer is not limited to Ti, and Cr or NiCr may be used instead, for example.

One of the unique features of the magnetic sensor device 1 of the present preferred embodiment is that the IDT electrode 3 is preferably made of a ferromagnetic metal as described above, and in addition, the duty ratio of the IDT electrode 3 preferably is higher than about 0.5 and lower than or equal to about 0.99, for example. As a result, the intensity of a magnetic field can be detected with high sensitivity, as will be described below. This will be described in more detail hereinafter.

Note that, in the present specifications, the duty ratio of an IDT electrode is a value expressed by W/(W+S), where W is the width of each of the electrode fingers of the IDT electrode 3 in the surface acoustic wave propagation direction and S is the size of a space between the neighboring electrode fingers in the surface acoustic wave propagation direction. Likewise, the duty ratios of the reflectors 4 and 5 are each expressed by W/(W+S), where the width of each of the electrode fingers is W, and the size of a space between the electrode fingers is S.

A magnetic sensor apparatus including the magnetic sensor device 1 described above will be described with reference to FIG. 2. A magnetic sensor apparatus 11 is preferably used, for example, as a magnetic open/close sensor apparatus.

In the magnetic sensor apparatus 11 illustrated in FIG. 2, a power supply 13 and a frequency counter 14 as a frequency measurement apparatus are connected to an oscillator circuit 12 that includes the magnetic sensor device 1. A surface acoustic wave is excited by applying an AC electric field to the magnetic sensor device 1 using the power supply 13. The magnetic sensor device 1 includes the IDT electrode 3 and the reflectors 4 and 5 respectively arranged on the two sides of the IDT electrode 3 in the surface acoustic wave propagation direction. The oscillator circuit 12 includes the magnetic sensor device 1 and an amplifier. The frequency counter 14 measures the oscillation frequency f of the oscillator circuit 12 that includes the magnetic sensor device 1 and the amplifier. This frequency is supplied to a personal computer 15.

When a magnetic field around the magnetic sensor device 1 changes, a change in magnetoelasticity occurs since a ferromagnetic metal exhibits the magnetostrictive effect. Further, distortion resulting from the magnetostriction is applied to the surface of the piezoelectric substrate 2. Hence, the acoustic velocity of a propagating surface acoustic wave, the resonant frequency of the surface acoustic wave resonator, and the like change.

Accordingly, when the magnetic field around the IDT electrode 3 changes, the frequency characteristics of the magnetic sensor device 1 change and the oscillation frequency f of the oscillator circuit 12 changes. The relationship between the oscillation frequency f and a magnetic flux density corresponding to the magnetic field strength around the IDT electrode 3 is stored in advance in the personal computer 15. Hence, the magnetic flux density around the IDT electrode 3 can be measured using a change in the frequency characteristics of the magnetic sensor device 1.

In the above description, an oscillator preferably includes a surface acoustic wave resonator and an amplifier, and the oscillation frequency was preferably measured with a counter. However, the frequency characteristics themselves, such as the resonant frequency fr, of the surface acoustic wave resonator may be measured using a network analyzer. The change in the oscillation frequency and the change in the resonant frequency show approximately the same value. Hereinafter, the change in the oscillation frequency and the change in the resonant frequency will both be referred to as the change in frequency.

For example, when the magnetic sensor apparatus is used as a magnetic open/close sensor of a cellular phone, the magnetic sensor device 1 is provided in the main body where a display and the like are arranged. A magnet is arranged in the cover that is opened or closed relative to the main body. In a state where the cover is closed, the magnet is near the magnetic sensor device 1, and as a result the magnetic flux density is very high, whereas in a state where the cover is opened, the magnet is spaced apart from the magnetic sensor device 1, and as a result the magnetic flux density is very low. Hence, the open/closed state of the cover can be detected from this change in the magnetic flux.

As described above, it is only required that at least a portion of the IDT electrode 3 is made of a ferromagnetic material, and the rest may be made of a material other than a ferromagnetic material. An example of such a case is a structure in which a portion is made of a ferromagnetic material and the rest is made of a non-magnetic material. In this case, when a high-conductivity material such as aluminum is used as a non-magnetic material, the electrical resistance of the electrode fingers may be lowered. Further, when a portion of the IDT electrode 3 is made of a ferromagnetic metal, the structure is not limited to a specific one. For example, a structure in which a ferromagnetic layer and a non-magnetic layer are stacked may be appropriately used.

As described above, in the IDT electrode 3, by using a ferromagnetic metal and a material other than a ferromagnetic metal together, the sensitivity of the magnetic sensor device 1 may be adjusted. Further, although only Ni is used as a ferromagnetic metal in the above-described preferred embodiment, the IDT electrode 3 may include a plurality of ferromagnetic metals. For example, a portion made of Ni and a portion made of Fe may be provided. Ferromagnetic metals made of different materials have different magnetostrictive characteristics. Hence, the sensitivity can be more finely adjusted by using, for example, Ni and Fe together and adjusting the mixing ratio.

Further, although the reflectors 4 and 5 are preferably made of Ni similarly to the IDT electrode 3, the reflectors 4 and 5 may be made of a material other than a ferromagnetic metal. For example, the reflectors 4 and 5 may be made of a non-magnetic material with a high reflection coefficient. In this case, the reflection coefficient can be easily optimized.

In addition, the reflectors 4 and 5 may also be formed such that a portion thereof is made of a ferromagnetic metal while the rest is made of a material other than a ferromagnetic metal.

Description will now be made regarding the fact that the sensitivity of the magnetic sensor device 1 can be increased by making the duty ratio of the IDT electrode be higher than about 0.5 and lower than or equal to about 0.99, for example.

A non-limiting example of the above-described magnetic sensor device 1 was made as follows. The above-described piezoelectric substrate 2 preferably defined by a 37 rotated Y-cut 90° X-propagation crystal substrate was prepared. A 5 nm Ti layer as an adhesive layer, the IDT electrode 3 made of Ni with a thickness of 300 nm, and the reflectors 4 and 5 made of Ni with a thickness of 300 nm were formed on the piezoelectric substrate 2 using a photolithography method. After that, a one-hour heating process at 300° C. was performed, whereby the magnetic sensor device 1 was obtained.

As described above, a magnetic open/close sensor includes a magnet and a magnetic sensor. The magnet used in this general magnetic open/close sensor is shaped like a cylinder. Normally, the diameter is several to ten millimeters, and the thickness is about several millimeters. FIG. 3 is a diagram illustrating magnetic flux density versus distance from a magnet surface for a first cylindrical neodymium magnet with a diameter of 2.5 mm and a thickness of 2 mm and for a second neodymium magnet with a diameter of 10 mm and a thickness of 2 mm. When using the first and second neodymium magnets with normal dimensions in such a magnetic open/close sensor system, the magnetic flux density at the surface of a magnet is several hundred milliteslas, and in a region within a distance of about 20 mm from the magnet surface, the magnetic flux density B is about 1 mT-100 mT. Hence, sensitivity that allows detection of at least 100 mT is required for a magnetic sensor device that is used in a magnetic open/close sensor.

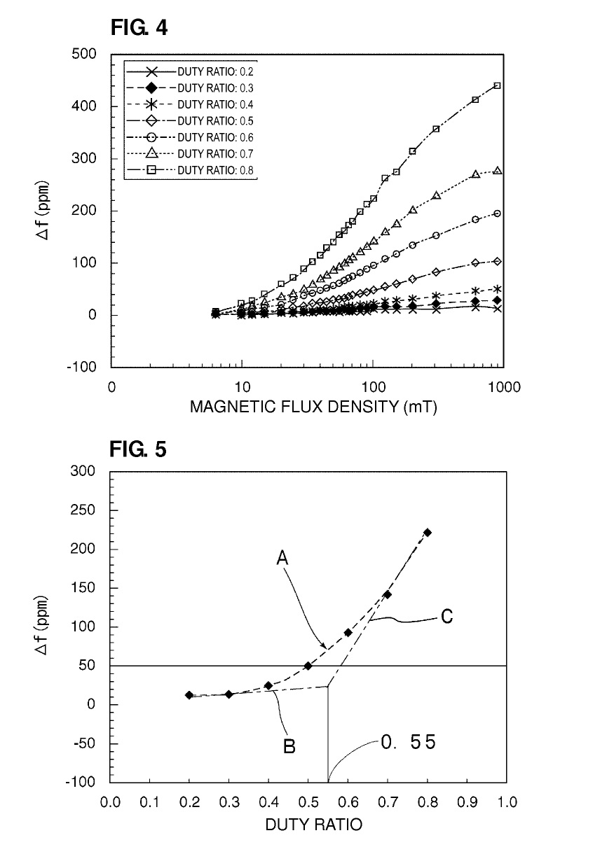

FIG. 4 is a diagram illustrating change in frequency Δf (ppm) versus magnetic flux density B for the magnetic sensor device described above in which the IDT electrode has a duty ratio of approximately 0.2, 0.3, 0.4, 0.5, 0.6, 0.7, or 0.8. Note that the magnetic flux density B was changed by adjusting the distance between the surface of the first neodymium magnet and the IDT electrode 3. The change in frequency Δf is expressed by (frx−fr)/fr, where fr is the resonant frequency at the time when the magnetic flux density around the magnetic sensor device 1 is zero and frx is the resonant frequency at the time when the magnetic flux density has changed as a result of the magnet having been brought closer to the magnetic sensor device 1.

As can be clearly seen from FIG. 4, the change in frequency due to a change in the magnetic flux density is increased as the duty ratio is increased. In particular, although the change in frequency Δf due to a change in the magnetic flux density B is small for the duty ratio of approximately 0.2-0.44, the change in frequency Δf becomes large when the duty ratio becomes larger than about 0.5. Hence, it can be seen that the magnetic flux density B can be measured with high accuracy when the duty ratio is made to be larger than about 0.5, for example.

FIG. 5 is a diagram illustrating change in frequency Δf versus duty ratio for the case where the magnetic flux density B is 100 mT, among the results illustrated in FIG. 4. As is clear from a curve A in FIG. 5, the change in frequency Δf increases as the duty ratio increases from about 0.2 to about 0.8.

By obtaining an inflection point of the curve A, a point with a duty ratio of about 0.55 is determined to be the inflection point. In other words, an intersecting point of a virtual line B obtained by approximating a portion of the curve A with a duty ratio lower than about 0.5 and a virtual line C obtained by approximating a portion of the curve A with a duty ratio higher than about 0.6 corresponds to the inflection point. The duty ratio at the inflection point is about 0.55. Hence, it can be seen that the detection sensitivity can be increased more effectively when the duty ratio is higher than about 0.55, for example.

Note that although the change in frequency Δf is increased as the duty ratio is increased, the duty ratio is less than 1, as is clear from the definition. When the IDT electrode is actually manufactured using photolithography, it is difficult to form the IDT electrode when the duty ratio is higher than about 0.99. Hence, the duty ratio preferably is about 0.99 or lower.

Accordingly, the detection sensitivity can be effectively increased when the duty ratio of the IDT electrode is made to be higher than about 0.5 and lower than or equal to about 0.99, preferably higher than or equal to about 0.55 and lower than or equal to about 0.99, for example.

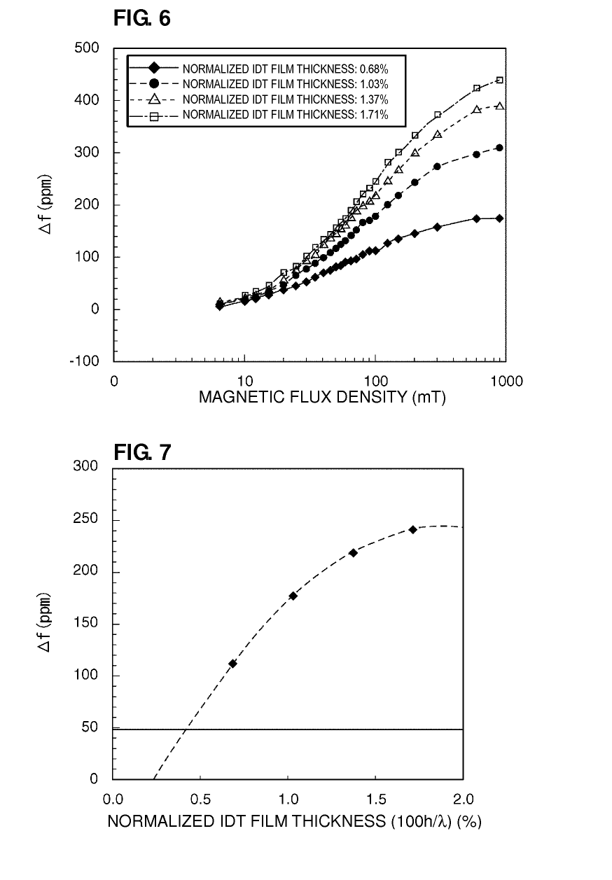

FIG. 6 is a diagram illustrating change in frequency Δf versus magnetic flux density in the magnetic sensor device 1 for the case where a normalized film thickness (h/λ)×100(%), which is obtained by normalizing the thickness (h) of the IDT electrode 3 using a wavelength λ, is approximately 0.68%, 1.03%, 1.37%, or 1.71%. Here, the duty ratio is always about 0.8.

As can be clearly seen from FIG. 6, the change in resonant frequency as the change in frequency Δf is increased as the normalized film thickness (100×h/λ) (%) of the IDT electrode 3 is increased.

FIG. 7 is a diagram illustrating change in frequency Δf versus normalized film thickness (100×h/λ) of the IDT electrode 3 for the case where the magnetic density is about 100 mT in FIG. 6. As is clearly seen from FIG. 7, the change in frequency Δf becomes about 50 ppm or more when the normalized film thickness of the IDT electrode 3 is larger than about 0.4%. The minimum detectable change in frequency in the magnetic open/close sensor is about 50 ppm, although dependent on the variation of the magnetic sensor device and measurement accuracy, for example. This is because, when the change in frequency Δf is about 50 ppm or more, a change in the change in frequency Δf resulting from a change in the magnetic flux density can be detected with high accuracy, as illustrated in FIG. 4 and FIG. 6. Hence, as is clear from FIG. 7, the normalized film thickness (100×h/λ) (%) of the IDT electrode 3 is preferably about 0.4% or more. As a result, the detection sensitivity can be effectively increased.

Further, as is clear from FIG. 7, although the change in frequency Δf increases as the normalized film thickness of the IDT electrode 3 is increased, the change in frequency Δf does not increase so much and the rate of increase in the change in frequency Δf is saturated when the normalized film thickness of the IDT electrode 3 exceeds about 1.6%.

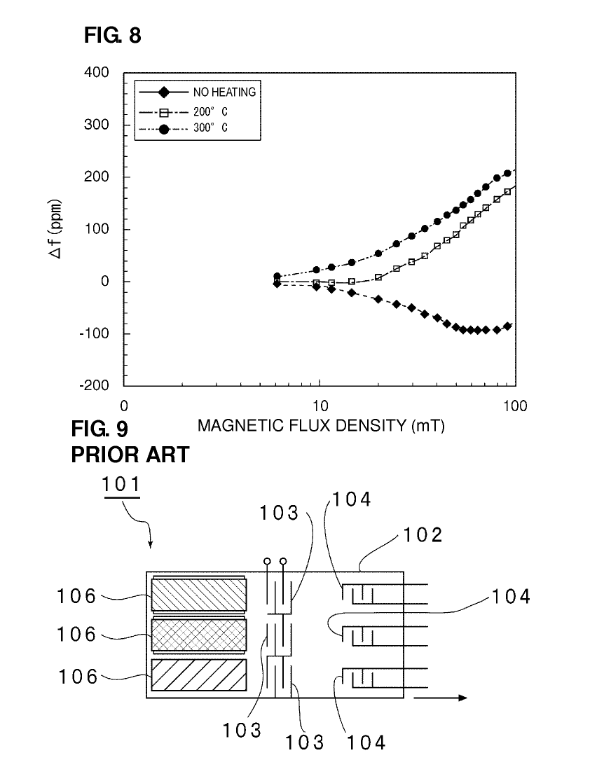

In the preferred embodiment and the exemplary experiment described above, a heating process at about 300° C. was performed after the IDT electrode had been formed. In the method of manufacturing the magnetic sensor apparatus according to a preferred embodiment of the present invention, a heating process is performed after the IDT electrode has been formed, as described above, whereby variation in the detection sensitivity of the magnetic sensor device is reduced. This will be described with reference to FIG. 8.

Referring to FIG. 8, three types of magnetic sensor device were obtained using a method similar to the method of manufacturing described in the above-described preferred embodiment, except that a process was performed after formation of the IDT electrode using the methods of the following first to third examples.

First example: no heating process

Second example: one-hour heating at a temperature of 200° C.

Third example: one-hour heating at a temperature of 300° C.

In other words, the third method is similar to the method of manufacturing the magnetic sensor of the preferred embodiment described above.

The relationship between the magnetic flux density and the change in frequency Δf for the three types of magnetic sensor obtained above was obtained. FIG. 8 illustrates the results.

As is clear from FIG. 8, although the change in frequency Δf changes as a result of a change in the magnetic flux density, the rate of change is small when a heating process is not performed.

On the other hand, when heating at about 200° C. or about 300° C. is performed, the change in frequency Δf considerably changes in the positive direction when the magnetic flux changes from about 6 mT to about 100 mT. Accordingly, when a heating process is performed after the formation of the IDT electrode, the detection sensitivity is effectively increased. Further, a heating process stabilizes the film quality of the IDT electrode, which is made of a ferromagnetic metal, at least in part, whereby manufacturing variations are reduced.

Note that the heating temperature is preferably about 200° C., or higher as is clear from FIG. 8. The upper limit of the heating temperature is preferably, although not limited to, about 500° C. or lower because the Curie point of crystal is about 570° C. However, the effect of heating depends on the duration of heating. Hence, the detection sensitivity is similarly increased even when heating at lower than about 200° C. is performed if the heating duration is long.

The heating duration is preferably one or two hours for heating at about 200° C. and about 300° C., and two hours or longer for heating at a temperature lower than this.

In the above-described preferred embodiment, an SH surface acoustic wave is used, but a surface acoustic wave other than an SH surface acoustic wave may be used. However, when an SH surface acoustic wave is used, the number of electrode fingers in the reflectors 4 and 5 can be reduced since the reflection coefficient is high. Hence, reduction in the size of the magnetic sensor device 1 is possible.

Further, an SH surface acoustic wave, whose acoustic velocity is about 4000 m/s to about 5000 m/s, is faster than other surface acoustic waves. Hence, even in the case where a high-frequency region is used, the width W of the electrode fingers of the IDT electrode can be increased. Accordingly, the manufacturing of the magnetic sensor device 1 is easy and the yield can be decreased. Hence, it is preferable to use an SH surface acoustic wave.

Note that although the magnetic sensor device 1 preferably has a structure of a one-port surface acoustic wave resonator in the above-described preferred embodiment, the electrode structure of the magnetic sensor device of the present invention is not limited to this. A two-port surface acoustic wave resonator or a longitudinally coupled or laterally coupled resonator filter may also be realized. In any case, a resonator-type surface acoustic wave device enables progress in size reduction compared with a transversal surface acoustic wave device.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A magnetic sensor device comprising:
a piezoelectric substrate; and
an IDT electrode disposed on the piezoelectric substrate; wherein
at least a portion of the IDT electrode is made of a ferromagnetic metal and a duty ratio of the IDT electrode is higher than about 0.5 and lower than or equal to about 0.99.

2. The magnetic sensor device according to claim 1, further comprising a first reflector and a second reflector respectively arranged on two sides of the IDT electrode, wherein a duty ratios of the first and second reflectors are higher than about 0.5 and lower than or equal to about 0.99.

3. The magnetic sensor device according to claim 1, wherein the piezoelectric substrate is a crystal substrate.

4. The magnetic sensor device according to claim 1, wherein, when a film thickness of the IDT electrode is H, and a wavelength of a surface acoustic wave excited by the IDT electrode is λ, a normalized film thickness (H/λ)×100(%) of the IDT electrode is larger or equal to about 0.4%.

5. A magnetic sensor apparatus comprising:
the magnetic sensor device according to claim 1; and
a frequency measurement apparatus that measures a change in frequency in the magnetic sensor device.

6. The magnetic sensor apparatus according to claim 5, wherein the magnetic sensor apparatus is a magnetic open/close sensor.

7. A method of manufacturing a magnetic sensor device comprising:
a step of forming an IDT electrode which has a duty ratio that is higher than about 0.5 and lower than or equal to about 0.99 and at least a portion of which is made of a ferromagnetic metal on a piezoelectric substrate; and
a heating step of performing a heating process after the step of forming of the IDT electrode.
